(19) United States
(12) Patent Application Publication
(10) Pub. No.: US 2025/0344618 A1
(43) Pub. Date: Nov. 6, 2025

(54) MEMORY DEVICE AND ELECTRONIC APPARATUSES INCLUDING THE SAME

(71) Applicants: Samsung Electronics Co., Ltd., Suwon-si (KR); KOREA ADVANCED INSTITUTE OF SCIENCE AND TECHNOLOGY, Daejeon (KR)

(72) Inventors: Yumin KIM, Suwon-si (KR); Kyungmin KIM, Daejeon (KR); Geunyoung KIM, Daejeon (KR); Garam PARK, Suwon-si (KR); Hyunjae SONG, Suwon-si (KR); Minhyun LEE, Suwon-si (KR); Seungdam HYUN, Suwon-si (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 19/196,386

(22) Filed: May 1, 2025

(30) Foreign Application Priority Data
May 3, 2024 (KR) 10-2024-0059408

(51) Int. Cl. H10N 70/00; G11C 13/00

(52) U.S. Cl. CPC H10N 70/8833; G11C 13/004; G11C 13/0069; G11C 13/0097; H10N 70/826

(57) ABSTRACT

A memory device includes a pillar, a gate oxide layer surrounding a side surface of the pillar, a resistance change layer surrounding a side surface of the gate oxide layer, and a plurality of interlayer isolation layers and a plurality of gate electrodes surrounding a side surface of the resistance change layer, the plurality of interlayer isolation layers and the plurality of gate electrodes alternating along a surface of the resistance change layer.

### CROSS-REFERENCE TO RELATED APPLICATION

This application is based on and claims priority under 35 U.S.C. § 119 to Korean Patent Application No. 10-2024-0059408, filed on May 3, 2024, in the Korean Intellectual Property Office, the disclosure of which is incorporated by reference herein in its entirety.

### BACKGROUND

### 1. Field

The disclosure relates to memory devices and electronic apparatuses including the same.

### 2. Description of the Related Art

As a semiconductor memory device, a non-volatile memory device is a memory device in which stored data is not destroyed even when the power supply is interrupted, and examples thereof include a programmable ROM (PROM), an erasable PROM (EPROM), an electrically erasable PROM (EEPROM), and flash memory devices.

Recently, vertical NAND (VNAND) devices, which require high integration and low power, have been studied as non-volatile memory devices, and research is being conducted to develop replacement products for VNAND devices to improve integration.

### SUMMARY

Some example embodiments of the disclosure provide memory devices with improved integration and an electronic apparatus including the same.

Additional aspects will be set forth in part in the description which follows and, in part, will be apparent from the description, or may be learned by practice of the presented example embodiments of the disclosure.

According to an example embodiment of the disclosure, a memory device includes a pillar, a gate oxide layer surrounding a side surface of the pillar, a resistance change layer surrounding a side surface of the gate oxide layer, and a plurality of interlayer isolation layers and a plurality of gate electrodes surrounding a side surface of the resistance change layer, the plurality of interlayer isolation layers and the plurality of gate electrodes alternating along a surface of the resistance change layer.

The resistance change layer may include a trap site.

The resistance change layer may include metal oxide or nitride.

The metal oxide may include TaOx, HfOx, or TiOx.

The nitride may include SiNx.

A thickness of the resistance change layer may be 10 nm or less.

The gate electrodes may include doped silicon or metal material.

The interlayer isolation layers may include silicon oxide, silicon nitride, silicon oxynitride, or alumina.

A thickness of each of the interlayer isolation layers may be 5 nm or less.

The gate oxide layer may include silicon oxide.

A thickness of the gate oxide layer may be 10 nm or less.

The memory device may further include an insulating layer between the gate electrodes and the resistance change layer.

The insulating layer may include silicon oxide, silicon nitride, silicon oxynitride, or alumina.

A thickness of the insulating layer may be 2 nm or less.

According to an example embodiment of the disclosure, a memory device includes a plurality of cell strings, and a plurality of interlayer isolation layers and a plurality of gate electrodes surrounding side surfaces of the plurality of cell strings, the plurality of interlayer isolation layers and the plurality of gate electrodes alternating along the side surfaces of the plurality of cell strings.

Each of the plurality of cell strings may include a pillar, a gate oxide layer surrounding a side surface of the pillar, and a resistance change layer surrounding a side surface of the gate oxide layer.

The resistance change layer may include a trap site.

The resistance change layer may include metal oxide or nitride.

Each of the plurality of cell strings may further include an insulating layer surrounding a side surface of the resistance change layer.

The insulating layer may include silicon oxide, silicon nitride, silicon oxynitride, or alumina.

According to an example embodiment of the disclosure, an electronic apparatus includes the memory device described above.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view illustrating a memory device according to an example embodiment;

FIG. 2 is a cross-sectional view of the memory device of FIG. 1 taken along line A-A′;

FIG. 3 is an enlarged cross-sectional view of portion A1 of FIG. 2;

FIGS. 4A and 4B are diagrams illustrating a write operation of a memory device according to an example embodiment;

FIGS. 5A and 5B are diagrams illustrating an erase operation of a memory device according to an example embodiment;

FIGS. 6A and 6B are diagrams illustrating a read operation of a memory device according to an example embodiment;

FIGS. 7A to 7C are energy band diagrams of a memory device according to an example embodiment;

FIG. 8 is a graph showing a word line operating voltage allowable region of a memory device according to an example embodiment;

FIG. 9 is a cross-sectional view illustrating a memory device according to an example embodiment;

FIG. 10 is an enlarged cross-sectional view of portion A2 of FIG. 9;

FIG. 11 is a diagram illustrating an energy band diagram of a memory device according to an example embodiment;

FIG. 12 is a block diagram schematically illustrating an electronic apparatus including a memory device according to an example embodiment; and

FIG. 13 is a block diagram schematically illustrating a memory system including a memory device, according to an example embodiment.

### DETAILED DESCRIPTION

Reference will now be made in detail to example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the attached drawings, a memory device and an electronic apparatus including the same according to various example embodiments will be described in detail. In the following drawings, the same reference numerals refer to the same components, and the size of each component in the drawings may be exaggerated for clarity and convenience of explanation. Also, some example embodiments described herein may have different forms and should not be construed as being limited to the descriptions set forth herein.

It will also be understood that when an element is referred to as being “on” or “above” another element, the element may be in direct contact with the other element or other intervening elements may be present. The singular forms include the plural forms unless the context clearly indicates otherwise. It should be understood that, when a part “comprises” or “includes” an element in the specification, unless otherwise defined, other elements are not excluded from the part and the part may further include other elements.

The use of the terms “a” and “an” and “the” and similar referents are to be construed to cover both the singular and the plural. The steps of all methods described herein can be performed in any suitable order unless otherwise indicated herein or otherwise clearly contradicted by context.

The connecting lines, or connectors illustrated in the various figures presented are intended to represent exemplary functional relationships and/or physical or logical couplings between the various elements. It should be noted that many alternative or additional functional relationships, physical connections or logical connections may be present in a practical device.

The use of any and all examples, or exemplary language (e.g., “such as”) provided herein, is intended merely to better illuminate the disclosure and does not pose a limitation on the scope of the disclosure unless otherwise claimed.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

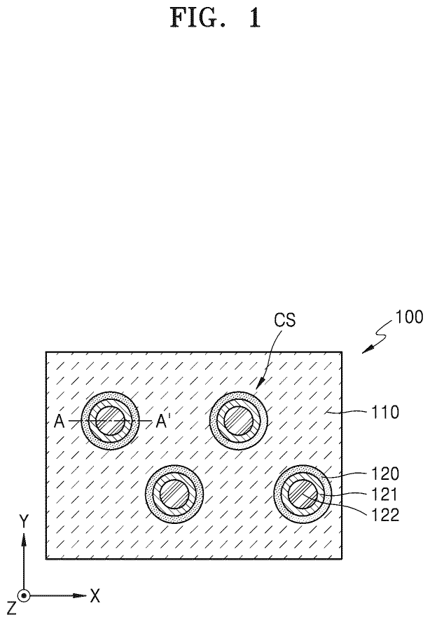

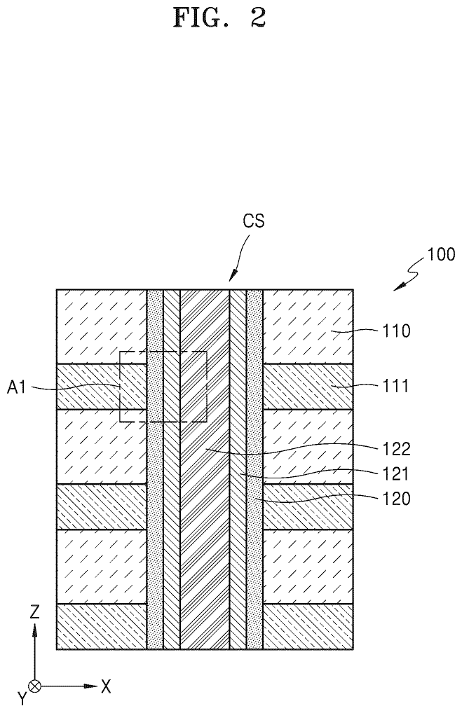

FIG. 1 is a cross-sectional view illustrating a memory device according to an example embodiment, and FIG. 2 is a cross-sectional view of the memory device of FIG. 1 taken along line A-A′.

Referring to FIGS. 1 and 2, a memory device 100 may include a plurality of cell strings CS, and a plurality of interlayer isolation layers 111 surrounding side surfaces of the plurality of cell strings CS and a plurality of gate electrodes 110 surrounding side surfaces of the plurality of cell strings CS. The plurality of interlayer isolation layers 111 and the plurality of gate electrodes 110 w are arranged alternately along the side surfaces of the plurality of cell strings CS.

The plurality of cell strings CS may include a pillar 122, a gate oxide layer 121 surrounding a side surface of the pillar 122, and a resistance change layer 120 surrounding a side surface of the gate oxide layer. The plurality of interlayer isolation layers 111 and the plurality of gate electrodes 110 may surround a side surface of the resistance change layer 120 and be alternately arranged along a surface of the resistance change layer 120.

The resistance change layer 120 may include a material having a resistance varying according to an applied voltage. The resistance change layer 120 may change from a high resistance state to a low resistance state or from a low resistance state to a high resistance state, according to a voltage applied to the gate electrode 110. A resistance change may be a phenomenon caused by electrons in the resistance change layer 120.

The resistance change layer 120 may include a trap site in which electrons are trapped. Information may be stored in the memory device 100 by trapping electrons in the trap site of the resistance change layer 120.

The resistance change layer 120 may include metal oxide or nitride. The metal oxide may include, for example, TaOx, HfOx, or TiOx. The nitride may include, for example, SiNx.

A thickness of the resistance change layer 120 may be, for example, about 20 nm or less. The thickness of the resistance change layer 120 may be, for example, about 10 nm or less.

The gate oxide layer 121 may include various insulating materials. The gate oxide layer 121 may include, for example, silicon oxide. The gate oxide layer 121 may be deposited conformally on the resistance change layer 120.

A thickness of the gate oxide layer 121 may be, for example, about 20 nm or less. The thickness of the gate oxide layer 121 may be, for example, about 10 nm or less.

The pillar 122 may include a material with excellent electrical conductivity. For example, the pillar 122 may include at least one of W, Ti, Ru, RuO₂, Ta, or TaN. The pillar 122 may include the same material as that of the gate electrode 110.

The gate electrode 110 may include a material that may provide or cause electrons to be trapped in the resistance change layer 120. The gate electrode 110 may include, for example, a metal material with excellent electrical conductivity such as gold (Au) or titanium (Ti), metal nitride, silicon doped with impurities, or a two-dimensional conductive material. However, this is merely an example, and the gate electrode 110 may include various other materials.

The gate electrode 110 including three layers is illustrated, but the gate electrode 110 is not limited thereto and may include two layers or three or more layers.

The interlayer isolation layer 111 may act as a spacer layer for insulation between the plurality of gate electrodes 110. The interlayer isolation layer 111 may include, for example, silicon oxide, silicon nitride, silicon oxynitride, or alumina.

A thickness of the interlayer isolation layer 111 may be, for example, about 10 nm or less. The thickness of the interlayer isolation layer 111 may be, for example, about 5 nm or less.

The interlayer isolation layer 111 including three layers is illustrated, but the interlayer isolation layer 111 is not limited thereto and may include two layers or three or more layers.

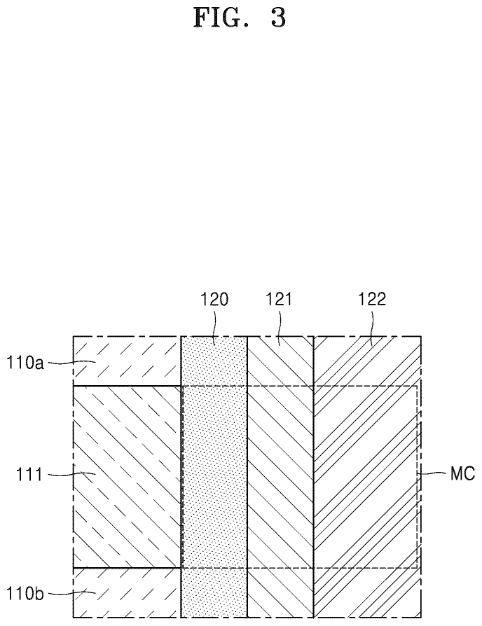

FIG. 3 is an enlarged cross-sectional view of portion A1 of FIG. 2.

Referring to FIG. 3, the memory device 100 may include a memory cell MC, and the memory cell MC may include the resistance change layer 120, the gate oxide layer 121, and the pillar 122.

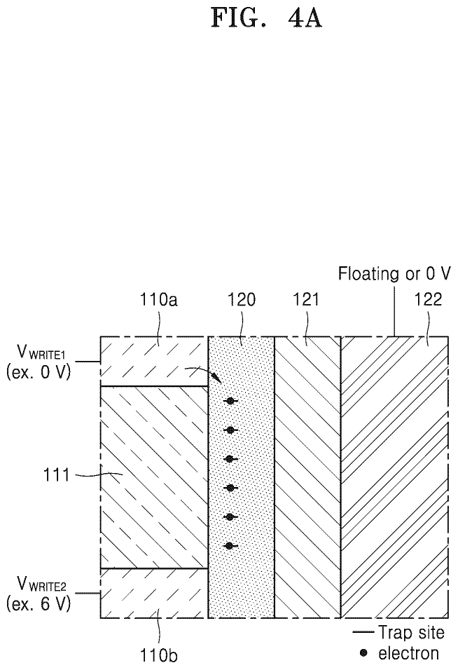

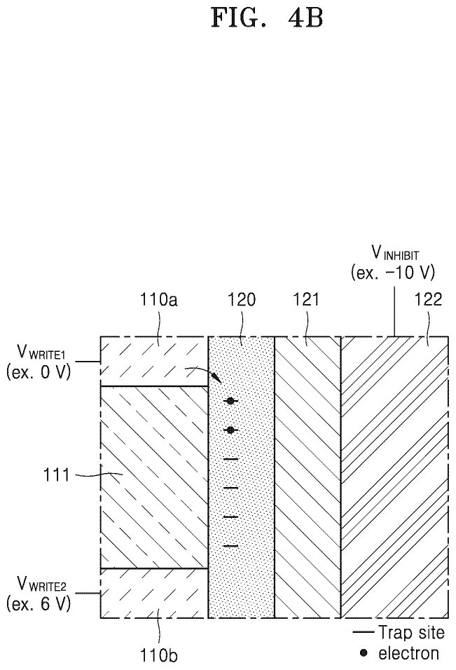

The memory device 100 may store information (data) in the memory cell MC by applying different voltages to a first gate electrode 110a and a second gate electrode 110b. Operations of writing, erasing, and reading information to or from the memory cell MC will be described later with reference to FIGS. 4A to 6B. In FIG. 3, the first gate electrode 110a is shown as an upper gate electrode and the second gate electrode 110b is shown as a lower gate electrode. However, on the contrary, the first gate electrode 110a may be a lower gate electrode and the second gate electrode 110b may be an upper gate electrode.

Among the plurality of cell strings CS, a cell string CS selected for writing, erasing, and reading operations may be determined through a voltage applied to the pillar 122. That is, 0 V may be applied to a selected cell string CS or floating voltage may be applied to the selected cell string CS, and V_{inhibit} may be applied to an unselected cell string CS.

FIGS. 4A and 4B are diagrams illustrating a write operation of a memory device according to an example embodiment.

FIG. 4A is a diagram illustrating a write operation in a selected cell string (CS in FIG. 1).

Referring to FIG. 4A, for example, a voltage of 0 V is applied to the first gate electrode 110a, and a voltage of 6 V is applied to the second gate electrode 110b. Electrons come out of the first gate electrode 110a to which 0 V voltage is applied and flow to the resistance change layer 120, and the electrons are trapped in a trap site in the resistance change layer 120. When the trap site is filled with electrons, electrons entering the resistance change layer 120 flow to the second gate electrode 110b, thereby allowing current to pass. When the trap site is filled with electrons, this may be defined as a low resistance state (LRS), and this may be referred to as a SET operation.

Here, a 0 V voltage may be applied to the pillar 122 or floating voltage may be applied to the pillar 122, and accordingly, injection of electrons from the first gate electrode 110a to the resistance change layer 120 may be smoothly performed.

FIG. 4B is a diagram illustrating a write operation in an unselected cell string (CS in FIG. 1).

Referring to FIG. 4B, the example embodiment of FIG. 4B is the same as the example embodiment of FIG. 4A in that a 0 V voltage is applied to the first gate electrode 110a and a voltage of 6 V is applied to the second gate electrode 110b, but there is a difference in that V_{inhibit} of −10 V is applied to the pillar 122. By applying V_{inhibit} of −10 V to the pillar 122, electron injection from the first gate electrode 110a into the resistance change layer 120 may be suppressed. Accordingly, a write operation is not performed on the unselected cell string (CS in FIG. 1) and remains in a high resistance state (HRS).

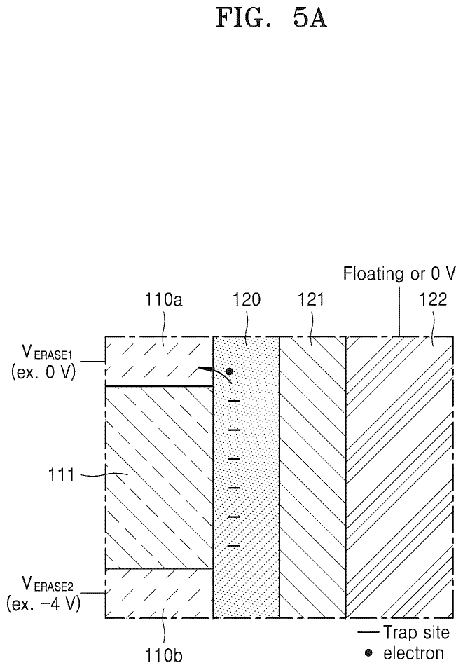

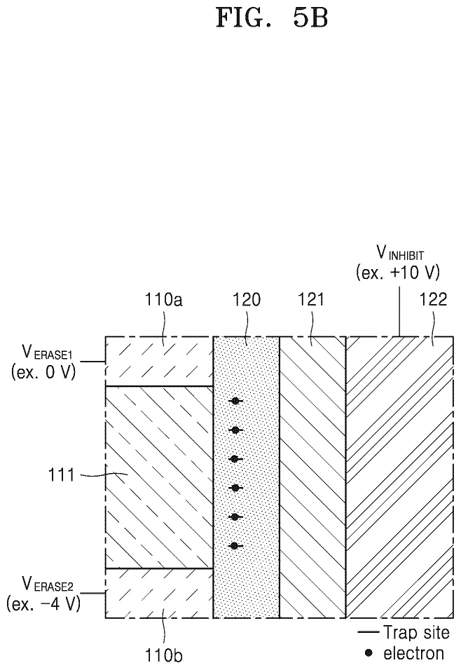

FIGS. 5A and 5B are diagrams illustrating an erase operation of a memory device according to an example embodiment.

FIG. 5A is a diagram illustrating an erase operation in a selected cell string (CS in FIG. 1).

Referring to FIG. 5A, for example, a 0 V voltage is applied to the first gate electrode 110a, and a voltage of −4 V is applied to the second gate electrode 110b. Meanwhile, an absolute value of a voltage applied to the second gate electrode 110b during the erase operation is less than an absolute value of a voltage applied to the second gate electrode 110b during the write operation.

When a negative voltage is applied to the second gate electrode 110b, electrons trapped in the trap site in the resistance change layer 120 escape to the first gate electrode 110a, thereby reducing or preventing current from flowing. This may be defined as a high resistance state (HRS), and may be referred to as a RESET operation.

FIG. 5B is a diagram illustrating an erase operation in an unselected cell string (CS in FIG. 1).

Referring to FIG. 5B, applying a 0 V voltage to the first gate electrode 110a and applying a voltage of −4 V to the second gate electrode 110b is the same as in the example embodiment of FIG. 5A, but there is a difference in that V_{inhibit} of +10 V is applied to the pillar 122. As V_{inhibit} of +10 V is applied to the pillar 122, electrons trapped in the trap site of the resistance change layer 120 may not escape to the first gate electrode 110a. Accordingly, the erase operation may not be performed on the unselected cell string (CS in FIG. 1).

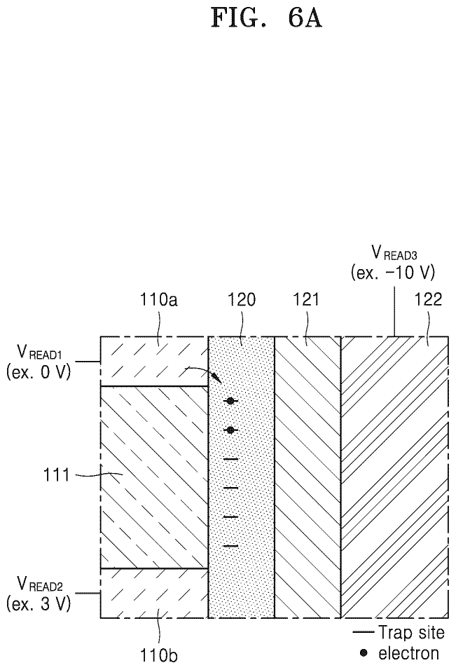

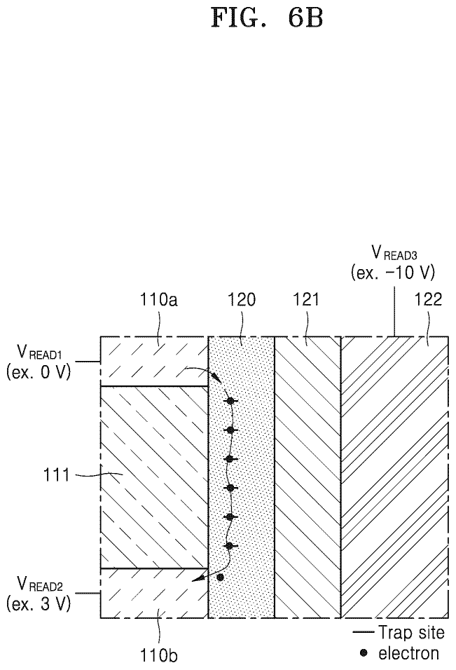

FIGS. 6A and 6B are diagrams illustrating a read operation of a memory device, according to an example embodiment.

FIG. 6A is a diagram describing a read operation in an erased state.

Referring to FIG. 6A, for example, a 0 V voltage is applied to the first gate electrode 110a, a voltage of 3 V is applied to the second gate electrode 110b, and a voltage of −10 V is applied to the pillar 122. Here, a small number of electrons are injected into the resistance change layer 120 from the first gate electrode 110a, the electrons are trapped in the trap site, and current does not flow. No current flowing indicates that the information has been erased.

FIG. 6A is a diagram describing a read operation in a written state.

Referring to FIG. 6B, for example, a 0 V voltage is applied to the first gate electrode 110a, a voltage of 3 V is applied to the second gate electrode 110b, and a voltage of −10 V is applied to the pillar 122. Here, a small number of electrons are injected into the resistance change layer 120 from the first gate electrode 110a, but since the electrons are already trapped in the trap site, and a current flows. The current flowing indicates that information is written.

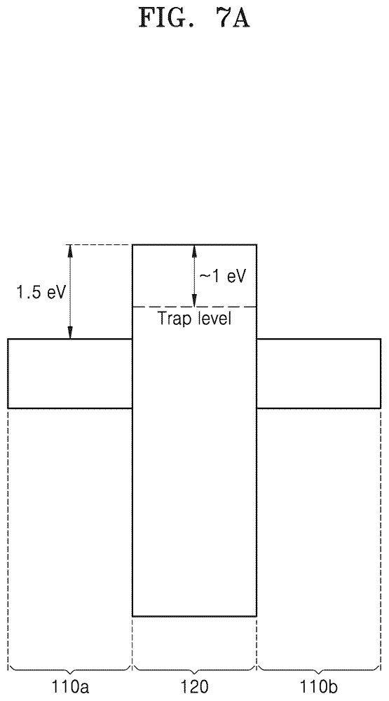

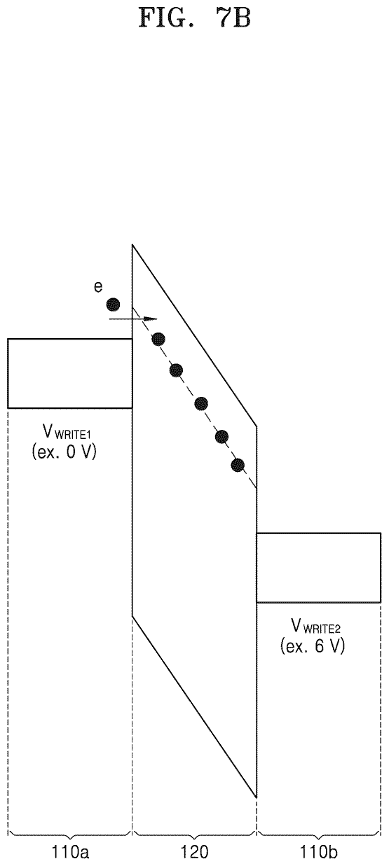

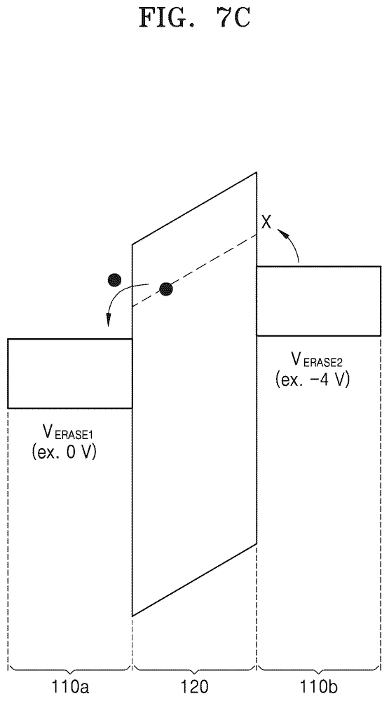

FIGS. 7A to 7C are energy band diagrams of a memory device according to an example embodiment.

In a memory device according to an example embodiment, n-type doped silicon is used as the first gate electrode 110a and the second gate electrode 110b, and HfOx is used as the resistance change layer 120.

FIG. 7A is an energy band diagram showing a case where no voltage is applied to the first gate electrode 110a and the second gate electrode 110b, FIG. 7B is an energy band diagram showing a write operation of a memory device, and FIG. 7C is an energy band diagram showing a case of an erase operation of a memory device.

Referring to FIG. 7A, in a state where no voltage is applied, the Fermi level of silicon forming the first gate electrode 110a and the Fermi level of the second gate electrode 110b are lower than a trap level of HfOx forming the resistance change layer 120. Here, it is assumed that the Fermi level of highly doped silicon is equal to a conduction band edge of silicon.

Referring to FIG. 7B, a 0 V voltage is applied to the first gate electrode 110a, and a positive voltage (e.g., 6 V) with a high absolute value compared to the erase operation is applied to the second gate electrode 110b. Here, band tilting of the resistance change layer 120 occurs. Accordingly, a region is generated where the trap level of HfOx forming the resistance change layer 120 is lower than the Fermi level of silicon forming the first gate electrode 110a, and the write operation occurs. During the write operation, electrons are injected from the first gate electrode 110a to the resistance change layer 120 to fill a trap site of the resistance change layer 120. Here, tunneling of electrons may occur from the first gate electrode 110a to the resistance change layer 120.

Referring to FIG. 7C, a 0 V voltage is applied to the first gate electrode 110a, and a negative voltage (for example, −4 V) with a low absolute value compared to the write operation is applied to the second gate electrode 110b. Here, band tilting of the resistance change layer 120 occurs. Accordingly, the electrons trapped in the resistance change layer 120 escape through the first gate electrode 110a and the erase operation occurs. However, electrons from the second gate electrode 110b are not injected into the resistance change layer 120 due to a barrier between the trap level of silicon forming the second gate electrode 110b and the trap level of HfOx forming the resistance change layer 120.

As an absolute value of a voltage applied to the second gate electrode 110b during the write operation is set to be greater than an absolute value of a voltage applied to the second gate electrode 110b during the erase operation, tunneling of electrons occurs from the first gate electrode 110a to the resistance change layer 120 during the write operation, but tunneling of electrons from the second gate electrode 110b to the resistance change layer 120 may not occur during the erase operation.

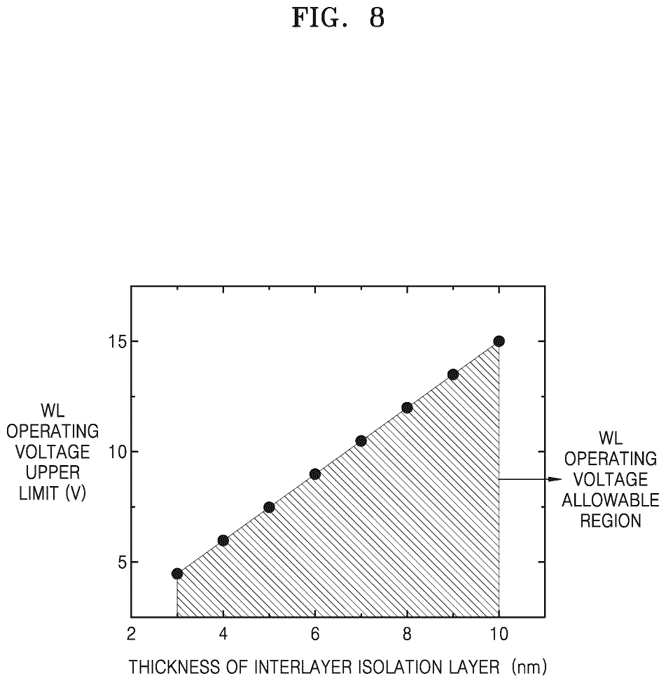

FIG. 8 is a graph showing a word line operating voltage allowable region of a memory device according to an example embodiment.

FIG. 8 shows an allowable operating voltage of a word line WL when SiO₂ is used as the interlayer isolation layer (111 in FIG. 3). A word line operating voltage refers to a voltage applied to the gate electrode (110 in FIG. 2).

According to a material and thickness of the interlayer isolation layer (111 in FIG. 3), the word line operating voltage should be limited to a range equal to or below a breakdown voltage of the interlayer isolation layer (111 in FIG. 3). The word line operating voltage is to have a value less than a breakdown electric field theory value of the interlayer isolation layer (111 in FIG. 3) multiplied by a thickness of the interlayer isolation layer (111 in FIG. 3).

The breakdown electric field theoretical value of SiO₂ is about 15 MV/cm, and accordingly, the hatched area in FIG. 8 represents an area where the word line operating voltage is allowed according to the thickness of the interlayer isolation layer (111 in FIG. 3).

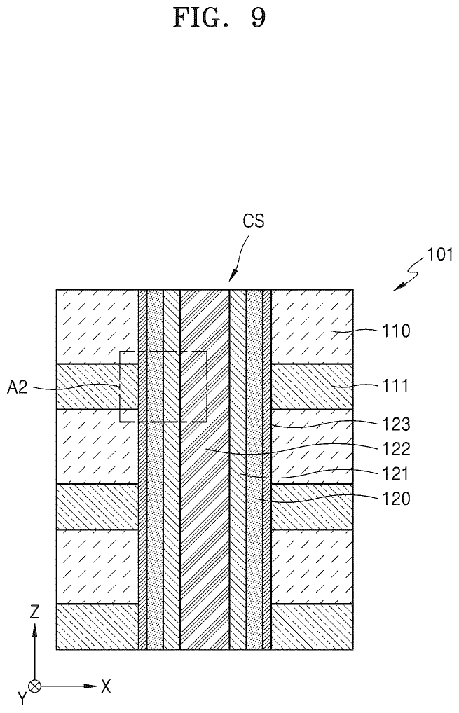

FIG. 9 is a cross-sectional view illustrating a memory device according to an example embodiment.

Referring to FIG. 9, a memory device 101 may include a plurality of cell strings CS, a plurality of interlayer isolation layers 111, and a plurality of gate electrodes 110. The plurality of interlayer isolation layers 111 and the plurality of gate electrodes 110 surround side surfaces of the plurality of cell strings CS and are arranged alternately along the side surfaces of the plurality of cell strings CS.

The plurality of cell strings CS may include a pillar 122, a gate oxide layer 121 surrounding a side surface of the pillar 122, a resistance change layer 120 surrounding a side surface of the gate oxide layer 121, and an insulating layer 123 surrounding a side surface of the resistance change layer 120.

The insulating layer 123 may be provided between the gate electrode 110 and the resistance change layer 120 to insulate the gate electrode 110 and the resistance change layer 120 from each other. The insulating layer 123 may include, for example, silicon oxide, silicon nitride, silicon oxynitride, or alumina.

The insulating layer 123 may have a thickness sufficiently thin to allow electron tunneling to occur. For example, the insulating layer 123 may be about 3 nm or less. For example, the insulating layer 123 may be about 2 nm or less. The insulating layer 123 may have a thickness thin enough to allow tunneling of electrons, so that electrons may pass through tunneling when a write voltage or an erase voltage is applied.

The insulating layer 123 may be naturally formed of native oxide. However, the insulating layer 123 is not limited thereto and may be formed by atomic layer deposition (ALD).

The insulating layer 123 may act as a barrier to reduce or prevent electrons trapped in the resistance change layer 120 from escaping. By including the insulating layer 123, the memory device 101 of FIG. 9 may have improved retention characteristics.

The memory device 101 of FIG. 9 may be the same as the memory device 100 of FIG. 1 except for the insulating layer 123 being further included. In describing the example embodiment of FIG. 9, details that overlap with those with respect to FIGS. 1 and 2 will be omitted.

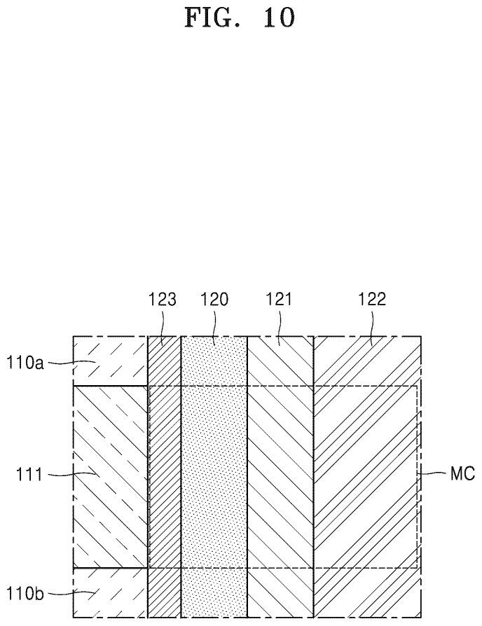

FIG. 10 is an enlarged cross-sectional view of portion A2 of FIG. 9.

Referring to FIG. 10, the memory device 101 may include a memory cell MC, and the memory cell MC may include the resistance change layer 120, the gate oxide layer 121, the pillar 122, and the insulating layer 123.

The memory device 101 may store information (data) in the memory cell MC by applying different voltages to the first gate electrode 110a and the second gate electrode 110b. Operations of writing, erasing, and reading information into or from the memory cell MC have been described above with reference to FIGS. 4A to 6B. In FIG. 10, the first gate electrode 110a is shown as an upper gate electrode and the second gate electrode 110b is shown as a lower gate electrode. However, on the contrary, the first gate electrode 110a may be a lower gate electrode and the second gate electrode 110b may be an upper gate electrode.

Among the plurality of cell strings CS, the cell string CS selected for writing, erasing, and reading operations may be determined through a voltage applied to the pillar 122. That is, a voltage of 0 V may be applied to a selected cell string CS or floating voltage may be applied to the selected cell string CS, and V_{inhibit} may be applied to an unselected cell string CS.

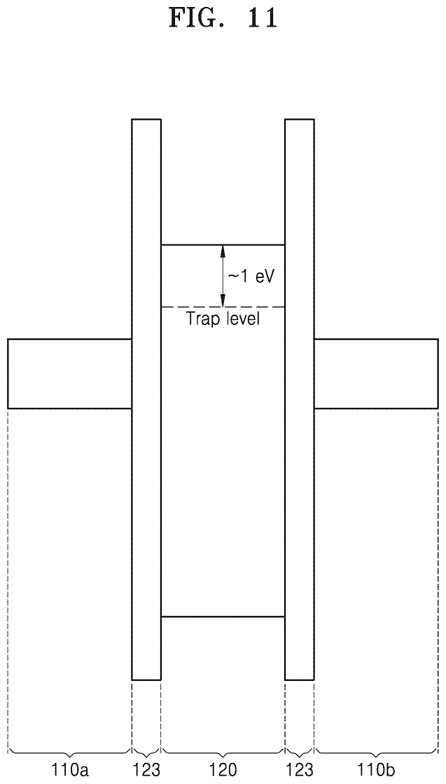

FIG. 11 is a diagram illustrating an energy band diagram of a memory device according to an example embodiment.

In a memory device according to an example embodiment, n-type doped silicon is used as the first gate electrode 110a and the second gate electrode 110b, and HfOx is used as the resistance change layer 120, and SiO₂ is used as the insulating layer 123.

Referring to FIG. 11, in a state where no voltage is applied, the Fermi level of silicon forming the first gate electrode 110a and the second gate electrode 110b is lower than a trap level of HfOx forming the resistance change layer 120.

The difference from the example embodiment of FIG. 7A is that, as the insulating layer 123 is between the first gate electrode 110a and the resistance change layer 120 and between the second gate electrode 110b and the resistance change layer 120, the insulating layer 123 acts as a barrier and thus it is difficult for electrons trapped in the resistance change layer 120 to escape. However, the insulating layer 123 may have a thickness thin enough to allow tunneling of electrons, so that electrons may pass through tunneling when a write voltage or erase voltage is applied.

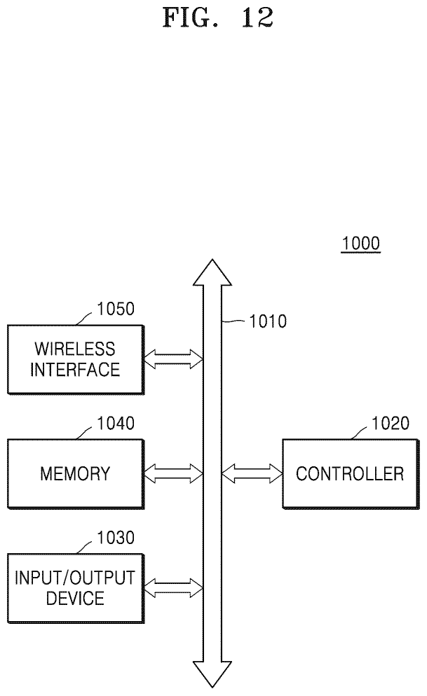

FIG. 12 is a block diagram schematically illustrating an electronic apparatus including a memory device according to an example embodiment.

Referring to FIG. 12, an electronic apparatus 1000 according to an example embodiment may include a personal digital assistant (PDA), a laptop computer, a portable computer, a web tablet, a cordless phone, a mobile phone, a digital music player, a wired or wireless electronic apparatus or a composite electronic apparatus including at least two of these. The electronic apparatus 1000 may include a controller 1020, an input/output device 1030 such as a keypad, a keyboard, and a display, a memory 1040, and a wireless interface 1050 that are coupled to each other through a bus 1010.

The controller 1020 may include, for example, one or more microprocessors, digital signal processors, microcontrollers, or the like. The memory 1040 may be used to store instructions executed by the controller 1020, for example.

The memory 1040 may be used to store user data. The memory 1040 may include at least one of the memory devices 100 and 101 according to an example embodiment.

The electronic apparatus 1000 may use the wireless interface 1050 to transmit data to or receive data from a wireless communication network that communicates using radio frequency (RF) signals. For example, the wireless interface 1050 may include an antenna, a wireless transceiver, etc. The electronic apparatus 1000 may be used in communication interface protocols such as 3rd generation communication systems such as code-division multiple access (CDMA), the Global System for Mobile Communications GSM, North American Digital Cellular (NADC), extended time division multiple access (E-TDMA), Wideband Code Division Multiple Access (WCDAM), and CDMA2000.

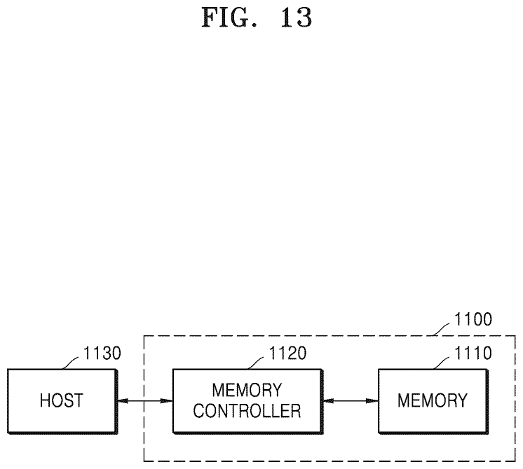

FIG. 13 is a block diagram schematically illustrating a memory system including a memory device, according to an example embodiment.

Referring to FIG. 13, a memory device according to an example embodiment may be used to implement a memory system. A memory system 1100 may include a memory 1110 and a memory controller 1120 for storing large amounts of data. The memory controller 1120 controls the memory 1110 to read or write data stored in the memory 1110 in response to a read/write request from the host 1130. The memory controller 1120 may configure an address mapping table to map an address provided from the host 1130, such as a mobile device or a computer system, to a physical address of the memory 1110. The memory 1110 may include at least one of the memory devices 100 and 101 according to an example embodiment.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to the memory device of the disclosure and the electronic apparatus including the same, the operating voltage may be lowered by including a new structure that replaces the existing VNAND, and thus reducing the thickness of the interlayer isolation layer and improving down-scaling of the device. A memory device and an electronic apparatus including the memory device are described above with reference to the example embodiments illustrated in the drawings. However, the descriptions are only examples, and one of ordinary skill in the art may understand that various modifications and equivalent example embodiments may be made from the descriptions. The disclosed example embodiments should be considered in a descriptive sense only and not for purposes of limitation. The scope of the disclosure is defined not by the detailed description of the disclosure but by the appended claims, and all differences within the scope of the claims will be construed as being included in the disclosure.

According to the memory device of the disclosure, the operating voltage may be reduced, thereby reducing the thickness of the interlayer isolation layer and thus enabling down-scaling of the device.

What is claimed is:

1. A memory device comprising:
a pillar;
a gate oxide layer surrounding a side surface of the pillar;
a resistance change layer surrounding a side surface of the gate oxide layer; and
a plurality of interlayer isolation layers and a plurality of gate electrodes surrounding a side surface of the resistance change layer, the plurality of interlayer isolation layers and the plurality of gate electrodes alternating along a surface of the resistance change layer.

2. The memory device of claim 1, wherein the resistance change layer comprises a trap site.

3. The memory device of claim 1, wherein the resistance change layer comprises metal oxide or nitride.

4. The memory device of claim 3, wherein the metal oxide comprises TaOx, HfOx, or TiOx.

5. The memory device of claim 3, wherein the nitride comprises SiNx.

6. The memory device of claim 1, wherein a thickness of the resistance change layer is 10 nm or less.

7. The memory device of claim 1, wherein the gate electrodes comprise doped silicon or a metal material.

8. The memory device of claim 1, wherein the interlayer isolation layers comprise silicon oxide, silicon nitride, silicon oxynitride, or alumina.

9. The memory device of claim 1, wherein a thickness of each of the interlayer isolation layers is 5 nm or less.

10. The memory device of claim 1, wherein the gate oxide layer comprises silicon oxide.

11. The memory device of claim 1, wherein a thickness of the gate oxide layer is 10 nm or less.

12. The memory device of claim 1, further comprising:
an insulating layer between the gate electrodes and the resistance change layer.

13. The memory device of claim 12, wherein the insulating layer comprises silicon oxide, silicon nitride, silicon oxynitride, or alumina.

14. The memory device of claim 12, wherein a thickness of the insulating layer is 2 nm or less.

15. A memory device comprising:
a plurality of cell strings; and
a plurality of interlayer isolation layers and a plurality of gate electrodes surrounding side surfaces of the plurality of cell strings, the plurality of interlayer isolation layers and the plurality of gate electrodes alternating along the side surfaces of the plurality of cell strings,
wherein each of the plurality of cell strings includes a pillar, a gate oxide layer surrounding a side surface of the pillar, and a resistance change layer surrounding a side surface of the gate oxide layer.

16. The memory device of claim 15, wherein the resistance change layer comprises a trap site.

17. The memory device of claim 15, wherein the resistance change layer comprises metal oxide or nitride.

18. The memory device of claim 15, wherein each of the plurality of cell strings further includes an insulating layer surrounding a side surface of the resistance change layer.

19. The memory device of claim 18, wherein the insulating layer comprises silicon oxide, silicon nitride, silicon oxynitride, or alumina.

20. An electronic apparatus comprising the memory device according to claim 1.
